(19) United States
(12) Patent Application Publication
(10) Pub. No.: US 2008/0166527 A1
(43) Pub. Date: Jul. 10, 2008

(54) CVD-coated cemented carbide insert for toughness demanding short hole drilling operations

(75) Inventors: Anders Lenander, Tyreso (SE); Jan Kjellgren, Kista (SE); Torbjorn Agren, Falun (SE); Stefan Reinebrandt, Uppsala (SE); Joakim Andersson, Osthammar (SE); Robert Granstrom, Uppsala (SE)

Correspondence Address: DRINKER BIDDLE & REATH (DC), 1500 K STREET, N.W., SUITE 1100, WASHINGTON, DC, 20005-1209, US

(73) Assignee: SANDVIK INTELLECTUAL PROPERTY AB

(21) Appl. No.: 12/003,198

(22) Filed: Dec. 20, 2007

(30) Foreign Application Priority Data
Dec. 27, 2006 (SE) 0602812-0

(51) Int. Cl. C23C 16/36; C23C 30/00; B32B 15/00

(52) U.S. Cl. 428/194; 427/249.19

(57) ABSTRACT

The present invention relates to a coated cutting insert with excellent toughness properties particularly useful for toughness demanding short hole drilling in general steel materials and a method of making the same. The inserts comprise a substrate and a coating. The substrate comprises WC, from about 8 to about 11 wt-% Co and from about 0.2 to about 0.5 wt-% Cr with an average WC-grain size of from about 0.5 to about 1.5 μm and a CW-ratio of from about 0.80 to about 0.90. The coating comprises
a first (innermost) layer of TiCₓN_{y}O_{z} with a thickness less than about 1.5 μm,
a layer of TiCₓN_{y}O_{z} with a thickness of from about 1 to about 8 μm with columnar grains,
a layer of fine-grained grain κ-Al₂O₃ with a thickness of from about 0.5 to about 5 μm and
a further layer less than about 1 μm thick of TiCₓN_{y}O_{z} whereby at the rake face the outermost TiCₓN_{y}O_{z}-layer and Al₂O₃-layer are fully or partly missing.

### BACKGROUND OF THE INVENTION

The present invention relates to a CVD coated cutting tool insert particularly useful for toughness demanding short hole drilling in general steel materials.

Drilling in metals is divided generally in two types: long hole drilling and short hole drilling. By short hole drilling is meant generally drilling to a depth of up to from about 3 to about 5 times the drill diameter.

Long hole drilling puts large demands on good chip formation, lubrication, cooling and chip transport. This is achieved through specially developed drilling systems with specially designed drilling heads fastened to a drill rod and fulfilling the above mentioned demands.

In short hole drilling, the demands are lower, enabling the use of simple helix drills formed either of solid cemented carbide or as solid tool steel or of tool steel provided with a number of cutting inserts of cemented carbide placed in such a way that they together form the necessary cutting edge. In the center of the head, a tough grade of insert is sometimes used and on the periphery a more wear resistant one. The cutting inserts are brazed or mechanically clamped.

The inserts are normally coated with a wear resistance coating. Two coating techniques are dominating: Physical Vapor Deposition (PVD) and Chemical Vapor Deposition (CVD).

WO 2006/080888 discloses PVD-coated cutting inserts with excellent toughness properties particularly useful for toughness demanding short hole drilling in low alloy and stainless steels. The inserts comprise a substrate and a coating. The substrate consists of WC with an average WC-grain size of from about 0.5 to about 1.5 μm, from about 8 to about 11 wt-% Co and from about 0.2 to about 0.5 wt-% Cr with a coating of a laminar, multilayered structure of TiN+Ti₁₋ₓAlₓN in polycrystalline, non-repetitive form deposited by arc evaporation technique.

WO 2006/080889 discloses CVD-coated cutting inserts for short hole drilling in steel at high speed and moderate feed. The cemented carbide includes WC, from about 2 to about 10 wt-% Co, and from about 4 to about 12 wt-% cubic carbides of metals from groups IVa, Va or VIa. The Co-binder phase is highly alloyed with W with a CW-ratio of from about 0.75 to about 0.90. The insert has a binder phase enriched and essentially cubic carbide free surface zone of a thickness of less than 20 μm. Along a line essentially bisecting the edge in the direction from the edge to the center of the insert, a binder phase content increases essentially monotonously until it reaches the bulk composition. Binder phase content at the edge in vol-% is from about 0.65 to about 0.75 times binder phase content of the bulk. The depth of the binder phase depletion is from about 100 to about 300 μm.

EP-A-1655390 discloses CVD-coated inserts particularly useful for milling under wet conditions. The inserts are characterised by a WC—Co cemented carbide substrate with a low content of cubic carbides and a coating including an inner layer of TiCₓN_{y} with columnar grains followed by a layer of κ-Al₂O₃ and a top layer of TiN.

PVD-coatings improve the wear resistance but also improve the toughness. CVD-coatings show superior wear resistance in comparison to PVD-coatings but inferior toughness properties. Consequently, CVD-coated inserts are most commonly used in operations with high demands regarding wear resistance and PVD-coated inserts in operations with high toughness demands.

### OBJECTS AND SUMMARY OF THE INVENTION

The object of the present invention is to provide a CVD-coated cutting tool insert useful for toughness demanding short hole drilling in steel.

In one embodiment of the invention there is provided cemented carbide inserts comprising a substrate and a coating with excellent toughness properties particularly useful for toughness demanding short hole drilling in general steels, said substrate comprising WC having an average grain size of from about 0.5 to about 1.5 μm and from about 8 to about 11 wt-% Co, and from about 0.2 to about 0.5 wt-% Cr whereby the cobalt binder phase has a CW-ratio of from about 0.80 to about 0.90 and the coating comprising a first, innermost layer of TiCₓN_{y}O_{z} with x+y+z=1 with equiaxed grains of a size less than about 0.5 μm and a total thickness less than about 1.5 μm, a second layer of TiCₓN_{y}O_{z} with x+y+z=1, with a thickness of from about 1 to about 8 μm with columnar grains and with an average diameter of less than about 5 μm, a layer of smooth, fine-grained, grain size from about 0.5 to about 2 μm Al₂O₃ consisting essentially of the κ-phase with a thickness of from about 0.5 to about 5 μm, a further layer less than about 1 μm thick of TiCₓN_{y}O_{z} with x+y+z=1, whereby at the rake face the outermost TiCₓN_{y}O_{z}-layer and Al₂O₃-layer are fully or partly missing on 80% of the rake face surface area between the edge line and 100 μm inwards in the direction perpendicular to the edge line.

In another embodiment of the invention, there is provided a method of making coated cemented carbide inserts with excellent toughness properties comprising providing a cemented carbide substrate WC having an average grain size of from about 0.5 to about 1.5 μm, from about 8 to about 11 wt-% Co, and from about 0.2 to about 0.5 wt-% Cr by wetmilling powders with pressing agent, and small additions of carbon black or pure tungsten powder to obtain a CW-ratio in the sintered inserts of from about 0.80 to about 0.90 in a slurry, drying the slurry to a powder, compacting and sintering and after conventional post sintering treatment depositing a coating comprising a first, innermost layer of TiCₓN_{y}O_{z} with x+y+z=1, with equiaxed grains with size less than about 0.5 μm and a total thickness less than about 1.5 μm, using known CVD-methods, a layer of TiCₓN_{y}O_{z} with x+y+z=1 with a thickness of from about 1 to about 8 μm, with columnar grains and with an average diameter of about less than about 5 μm by MTCVD-technique with acetonitrile as the carbon and nitrogen source for forming the layer in the temperature range of from about 700 to about 900° C., a layer of smooth, fine-grained, grain size from about 0.5 to about 2 μm, Al₂O₃ consisting essentially of the κ-phase with a thickness of from about 0.5 to about 5 μm, using known CVD-methods and a further layer less than about 1 μm thick, of TiCₓN_{y}O_{z} with x+y+z=1 using known CVD-methods, fully or partly removing the outermost TiCₓN_{y}O_{z}-layer and Al₂O₃-layer on at least 80% of the rake face surface area between the edge line and 100 μm inwards in the direction perpendicular to the edge line.

### BRIEF DESCRIPTION OF THE DRAWINGS

FIG. 1 is light microscope photo showing that the (golden) top layer is intact at the clearance face (A) while it is fully removed on the rake face (B).

FIG. 2 is an SEM back scattered electron micrograph showing that the second TiCₓN_{y}O_{z} layer (light contrast) is exposed due to the removal of the alumina layer (dark contrast) at the area near the edge (C).

FIG. 3 is an SEM micrograph using back scattered electrons showing that the second TiCₓN_{y}O_{z} layer is exposed at most of the rake face (D).

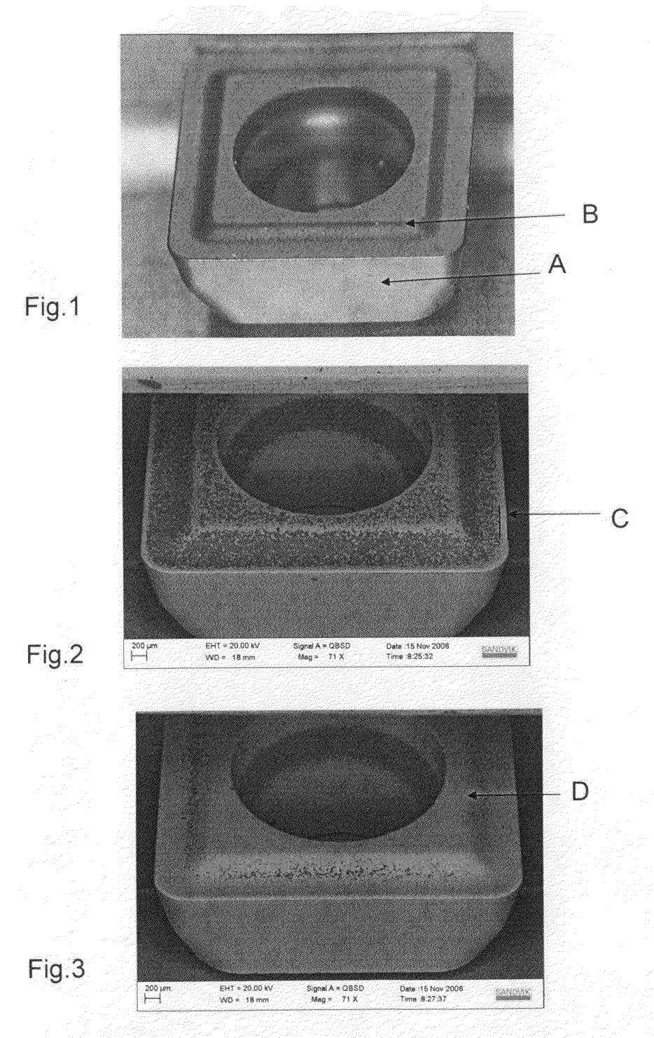

### DETAILED DESCRIPTION OF THE PREFERRED EMBODIMENTS

According to the invention, there is now provided cemented carbide inserts of a substrate and a coating with excellent toughness properties particularly useful for toughness demanding short hole drilling, in general of steels, the substrate comprising WC and from about 8 to about 11 wt-% Co, preferably from about 9.5 to about 10.5 wt-% Co and from about 0.2 to about 0.5 wt-% Cr. The WC-grains have an average grain size of from about 0.5 to about 1.5 μm.

The cobalt binder phase is rather highly alloyed with W. The content of W in the binder phase is expressed as the

CW-ratio=magnetic-% Co/wt-% Co

where magnetic-% Co is the weight percentage of magnetic Co and wt-% Co is the weight percentage of Co in the cemented carbide. The CW-value is a function of the W content in the Co binder phase. A CW-value of about 1 corresponds to a low W-content in the binder phase and a CW-value of about from about 0.75 to about 0.8 correspond to a high W-content in the binder phase. The CW-ratio in inserts according to the present invention shall be from about 0.80 to about 0.90.

The coating comprises:
a first (innermost) layer of TiCₓN_{y}O_{z} with x+y+z=1, preferably y greater than x and z less than about 0.2, most preferably y greater than about 0.8 and z=0, with equiaxed grains with size less than about 0.5 μm and a total thickness less than about 1.5 μm, preferably greater than about 0.1 μm;
a layer of TiCₓN_{y}O_{z} with x+y+z=1, preferably with z=0, x greater than about 0.3 and y greater than about 0.3, most preferably x greater than about 0.5, with a thickness of from about 1 to about 8 μm, preferably from about 2 to about 7 μm, most preferably less than about 6 μm, with columnar grains and with an average diameter of less than about 5 μm, preferably from about 0.1 to about 2 μm;
a layer of a smooth, fine-grained, grain size from about 0.5 to about 2 μm, Al₂O₃ consisting essentially of the κ-phase. However, the layer may contain small amounts, from about 1 to about 3 vol-%, of the θ- or the α-phases as determined by XRD-measurement. The Al₂O₃-layer has a thickness of from about 0.5 to about 5 μm, preferably from about 0.5 to about 2 μm, and most preferably from about 0.5 to about 1.5 μm. The Al₂O₃-layer is followed by a further layer, less than about 1 μm, preferably from about 0.1 to about 0.5 μm thick, of TiCₓN_{y}O_{z} with x+y+z=1, preferably with y greater than x and z less than about 0.3, most preferably y greater than about 0.8. The outermost TiCₓN_{y}O_{z}-layer and the Al₂O₃-layer are fully or partly removed on about 80% of the rake face surface area between the edge line and about 100 μm inwards, in the direction perpendicular to the edge line.

Furthermore, the second TiCₓN_{y}O_{z} layer at the rake face should be in the compressive stress state of from 0 to about 2500 MPa, preferably from about 500 to about 1500 MPa.

The invention also relates to a method of making coated cemented carbide inserts with excellent toughness properties particularly useful for toughness demanding short hole drilling in general steels and stainless steels. The cemented carbide comprises WC and from about 8 to about 11 wt-% Co, preferably from about 9.5 to about 10.5 wt-% Co and from about 0.2 to about 0.5 wt-% Cr. The WC-grains have an average grain size of from about 0.5 to about 1.5 μm. The raw materials powders are wet milled to form a slurry with a pressing agent, small additions of carbon black or pure tungsten powder to obtain a CW-ratio in the sintered inserts of from about 0.80 to about 0.90. After the wet milling, the slurry is dried to a powder, compacted and sintered. After conventional post sintering treatment a coating comprising:
a first (innermost) layer of TiCₓN_{y}O_{z} with x+y+z=1, preferably y greater than x and z less than about 0.2, most preferably y greater than about 0.8 and z=0, with equiaxed grains with size less than about 0.5 μm and a total thickness less than about 1.5 μm, preferably greater than about 0.1 μm, using known CVD-methods;
a layer of TiCₓN_{y}O_{z} with x+y+z=1, preferably with z=0, x greater than about 0.3 and y greater than about 0.3, most preferably x greater than about 0.5, with a thickness of from about 1 to about 8 μm, preferably from about 2 to about 7 μm, most preferably less than about 6 μm, with columnar grains and with an average diameter of about less than about 5 μm, preferably from about 0.1 to about 2 μm, using preferably MTCVD-technique using acetonitrile as the carbon and nitrogen source for forming the layer in the temperature range of from about 700 to about 900° C. The exact conditions, however, depend to a certain extent on the design of the equipment used and can be determined by the skilled artisan;
a smooth Al₂O₃-layer consisting essentially of κ-Al₂O₃ is deposited under known conditions, such as disclosed in, e.g., EP-A-523 021, hereby incorporated by reference in its entirety. The Al₂O₃ layer has a thickness of from about 0.5 to about 5 μm, preferably from about 0.5 to about 2 μm, and most preferably from about 0.5 to about 1.5 μm. A further layer less than about 1 μm, preferably from about 0.1 to about 0.5 μm thick of TiCₓN_{y}O_{z} is deposited, using known CVD-methods. The full or partial removal of the rake face top TiCₓN_{y}O_{z} layer and the Al₂O₃-layer can be obtained by wet blasting of the coated surface with fine grained (400-150 mesh) alumina powder.

### EXAMPLE 1

Inserts made of cemented carbide with composition WC+10 wt-% Co, 0.39 wt % Cr and average WC grain size of 1.0 μm and a CW-ratio of 0.86 were coated with a 0.5 μm equiaxed TiC_{0.05}N_{0.95}-layer (with a high nitrogen content corresponding to an estimated C/N-ratio of 0.05) followed by a 4 μm thick TiC_{0.54}N_{0.46}-layer, with columnar grains using MTCVD-technique, temperature 885-850° C. and CH₃CN as the carbon/nitrogen source. In subsequent steps during the same coating cycle, a 1.0 μm thick layer of Al₂O₃ was deposited using a temperature of 970° C. and a concentration of H₂S dopant of 0.4% as disclosed in EP-A-523 021. A 0.3 μm layer of TiN was deposited on top according to known CVD-technique. XRD-measurement showed that the Al₂O₃-layer consisted of 100% κ-phase.

### EXAMPLE 2

Inserts from Example 1 were treated by wet blasting with a blasting pressure of 2.2 bar. As a result of the blasting treatment all the top TiN-layer and parts of the Al₂O₃-layer at the rake face was removed. At the rake face area at the edge line and 100 μm inwards, in the direction perpendicular to the edge line, most of the alumina was gone and as a result the second TiC_{0.54}N_{0.46}-layer was exposed at >80% of this surface area. At the clearance face most of the top TiN layer was still intact.

The stress state in the second TiC_{0.54}N_{0.46}-layer was measured using X-ray diffraction. At the rake face the coating has compressive stress, −800 to −940 MPa. At the clearance face the stress state was tensile, +900 MPa.

The method for evaluating the stress state of the second TiC_{0.54}N_{0.46}-layer in this and the following examples was according the well known sin²ψ method as described by I. C. Noyan, J. B. Cohen, Residual Stress Measurement by Diffraction and Interpretation, Springer-Verlag, New York, 1987 (pp 117-130). The stress evaluation was carried out by using ψ-geometry on a X-ray diffractometer Bruker D8 Discover-GADDS equipped with laser-video positioning, Euler ¼-cradle, rotating anode as X-ray source (CuK_{α}-radiation) and an area detector (Hi-star). A collimator of size 0.5 mm was used to focus the beam. The analysis was performed on the TiCₓN_{y} (422) reflection using the goniometer settings 2θ=126°, ω=63° and Φ=0°, 90°, 180°, 270°. Eight ψ tilts between 0° and 70° were performed for each ν-angle. The sin²ψ method was used to evaluate the residual stress using the software DIFFRAC^{Plus} Stress32 v. 1.04 from Bruker AXS with the constants Young's modulus, E=480 GPa and Poisson's ratio, ν=0.20 and locating the reflection using the Pseudo-Voigt-Fit function. A biaxial stress state was confirmed and the average value was used as the residual stress value.

### EXAMPLE 3

Inserts from Example 1 were treated with a blasting pressure of 2.4 and 2.6 bar respectively. As a result most of the alumina layer on the rake face was removed.

The stress state in the second TiC_{0.54}N_{0.46}-layer was measured using X-ray diffraction. At the rake face the layer had compressive stress:

| | |
|---|---|
| 2.4 bar | −1840 MPa |
| 2.6 bar | −2400 MPa |

The stress state at the clearance face of the insert was tensile:

| | |
|---|---|
| 2.4 bar | +850 MPa |
| 2.6 bar | +860 MPa |

The exposed second TiC_{0.54}N_{0.46}-layer was intact apart from some small dots (<edge radius) at the very edge line. The Example shows that high blasting pressure resulting in high compressive stresses can be applied without any major damages on the second TiC_{0.54}N_{0.46}-layer.

### EXAMPLE 4

Inserts from Example 1 were treated by brushing of the edge line. The treatment resulted in a removal the top TiCₓN_{y}O_{z} layer at the edge line as well as generating a smooth edge as disclosed in e.g. U.S. Pat. No. 5,861,210.

### EXAMPLE 5

Inserts from Example 2 were tested and compared with inserts from Sandvik commercial grade GC4044 in a short hole drilling operation. The tested inserts were mechanically clamped on the periphery of the drill head. In the center, inserts from Sandvik commercial grade GC1044 were used. Tool life criteria: crater wear, plastic deformation, flank wear, or chipping >0.25 mm.

| | |
|---|---|
| Material: | Low alloy steel SS2541-03, 285 HB. |
| Emulsion: | Blasocut BC25, 8%. |
| Operation: | Through hole, 45 mm. |

| | A | B | C |
|---|---|---|---|
| Cutting Speed: | 200 m/min | 180 m/min | 160 m/min |
| Feed | 0.12 mm/r | 0.13 mm/r | 0.15 mm/r |

| | |
|---|---|
| Drill | Diameter 15 mm, 3XD |
| Insert Style: | CoroDrill 880-0202W05H-P, GR |

Results. A surprisingly significant difference in tool life, regarding plastic deformation and flank wear resistance, was seen. The inserts according to the invention showed a much improved flank wear resistance compared to the reference.

Drilled Length at Tool Life:

| | A | B | C |
|---|---|---|---|
| Inserts invention | 200 meters | >23 meters | 22 meters |
| Inserts reference | tool failure | after | |
| | 13 meters | 13 meters | 15 meters |

### EXAMPLE 6

Inserts from Example 2 were tested and compared with inserts from Sandvik commercial grade 4044 in a short hole drilling operation. The tested inserts were mechanically clamped on the periphery of the drill head. In the center, inserts from Sandvik commercial grade 1044 were used. Tool life criteria: crater wear, plastic deformation, flank wear, or chipping >0.25 mm.

| | |
|---|---|
| Material: | Low alloy steel SS2541-03, 285 HB. |
| Emulsion: | Blasocut BC25, 8%. |
| Operation: | Through hole, 48 mm. |

| | A | B |
|---|---|---|
| Cutting Speed: | 170 m/min | 195 m/min |
| Feed | 0.15 mm/r | 0.13 mm/r |

| | |
|---|---|
| Drill | Diameter 18 mm, 3XD |
| Insert Style: | CoroDrill 880-0303W06H-P, GR |

Results. A surprisingly significant difference in tool life, regarding plastic deformation and flank wear resistance, was seen. The inserts according to the invention showed a much improved flank wear resistance compared to the reference.

Drilled Length at Tool Life:

| | A | B |
|---|---|---|
| Inserts invention | >25 meters | 19 meters |
| Inserts reference | tool failure | after |
| | 14 meters | 13 meters |

### EXAMPLE 7

Inserts from Example 2 were tested and compared with inserts from Sandvik commercial grade 4044 in a short hole drilling operation. The tested inserts were mechanically clamped on the periphery of the drill head. In the center, inserts from Sandvik commercial grade 1044 were used. Tool life criteria: crater wear, plastic deformation, flank wear, or chipping >0.25 mm.

| | |
|---|---|
| Material: | Stainless steel SS2343, 160 HB. |
| Emulsion: | Blasocut BC25, 8%. |
| Operation: | Through hole, 40 mm. |

| | A | B | C |
|---|---|---|---|
| Cutting Speed: | 240 m/min | 220 m/min | 200/m/min |
| Feed | 0.10 mm/r | 0.10 mm/r | 0.11 mm/r |

| | |
|---|---|
| Drill | Diameter 15 mm, 3XD |
| Insert Style: | CoroDrill 880-0202W05H-P, LM |

Results. A surprisingly significant difference in tool life, regarding plastic deformation and flank wear resistance, was seen. The inserts according to the invention showed a much improved flank wear resistance compared to the inserts reference.

Drilled Length at Tool Life:

| | A | B | C |
|---|---|---|---|
| Inserts invention | 10 meters | >16 meters | >16 meters |
| Inserts reference | tool failure | after | |
| | 5 meters | 7 meters | 9 meters |

### EXAMPLE 8

Inserts from Example 2 were tested and compared with inserts from Sandvik commercial grades 4024 with respect to toughness in a short hole drilling operation. The tested inserts were mechanically clamped on the periphery of the drill head. In the center, inserts from Sandvik commercial grade 1044 were used. Tool life criteria: crater wear, plastic deformation, flank wear, or chipping >0.25 mm.

| | |
|---|---|
| Material: | Stainless steel SS2343, 160 HB. |
| Emulsion: | Blasocut BC25, 8%. |
| Operation: | Through hole, 50 mm. |
| Cutting speed: | 180 m/min |
| Feed: | 0.13 mm/r |
| Drill: | Diameter 18 mm, 3XD |
| Insert style: | CoroDrill 880-0303W06H-P, LM |

Results. An improvement in toughness behavior was seen. The inserts according to the invention showed a much improved toughness compared to the inserts reference.

Drilled Length at Tool Life:

| | |
|---|---|
| Inserts invention | >20 meters |
| Inserts reference | tool failure after 17 meters |

### EXAMPLE 9

Inserts from Example 2 and Example 4 were tested and compared with respect to toughness in a short hole drilling operation. The tested inserts were mechanically clamped on the periphery of the drill head. In the center, inserts from Sandvik commercial grade 1044 were used. Tool life criteria: crater wear, plastic deformation, flank wear, or chipping >0.25 mm.

| | |
|---|---|
| Material: | Low alloy steel SS2541-03, 285 HB. |
| Emulsion: | Blasocut BC25, 8%. |
| Operation: | Through hole, 45 mm. |
| Cutting speed: | 240 m/min |
| Feed: | 0.10 mm/r |
| Drill: | Diameter 15 mm, 3xD |
| Insert style: | CoroDrill 880-0202W05H-P, GR |

Results. A significant difference in toughness behavior was seen. The insert from Example 2 got controlled flank wear whilst the insert from Example 4 failed due to occurrence of a big crack penetrating half of the insert together with edge breakage adjacent to the crack.

Drilled Length at Tool Life:

| | |
|---|---|
| Inserts invention | 20 meters |
| Inserts Example 4 | tool failure after 9 meters |

Although the present invention has been described in connection with preferred embodiments thereof, it will be appreciated by those skilled in the art that additions, deletions, modifications, and substitutions not specifically described may be made without department from the spirit and scope of the invention as defined in the appended claims.

1. Cemented carbide inserts comprising a substrate and a coating with excellent toughness properties particularly useful for toughness demanding short hole drilling in general steels, said substrate comprising WC having an average grain size of from about 0.5 to about 1.5 μm and from about 8 to about 11 wt-% Co, and from about 0.2 to about 0.5 wt-% Cr whereby the cobalt binder phase has a CW-ratio of from about 0.80 to about 0.90 and the coating comprising:
a first, innermost layer of TiCₓN_{y}O_{z} with x+y+z=1 with equiaxed grains of a size less than about 0.5 μm and a total thickness less than about 1.5 μm,
a second layer of TiCₓN_{y}O_{z} with x+y+z=1, with a thickness of from about 1 to about 8 μm with columnar grains and with an average diameter of less than about 5 μm,
a layer of smooth, fine-grained, grain size from about 0.5 to about 2 μm Al₂O₃ consisting essentially of the κ-phase with a thickness of from about 0.5 to about 5 μm,
a further layer less than about 1 μm thick of TiCₓN_{y}O_{z} with x+y+z=1, whereby at the rake face the outermost TiCₓN_{y}O_{z}-layer and Al₂O₃-layer are fully or partly missing on 80% of the rake face surface area between the edge line and 100 μm inwards, in the direction perpendicular to the edge line.

2. Cemented carbide insert of claim 1 wherein the second TiCₓN_{y}O_{z} layer at the rake face has a compressive stress state of from 0 to about 2500 MPa.

3. Cemented carbide insert of claim 1 wherein said substrate comprises from about 9.5 to about 10.5 wt-% Co.

4. Cemented carbide insert of claim 1 wherein in said first layer, y greater than z and z is less than about 0.2 and said first layer has a total thickness greater that about 0.1 μm, in said second layer, z=0, x and y are each greater than about 0.3 and said second layer has a thickness of from about 2 to about 7 μm and said columnar grains have an average diameter of from about 0.1 to about 2 μm, said Al₂O₃ has a thickness of from about 0.5 to about 2 μm and said further layer of TiCₓN_{y}O_{z} being from about 0.1 to about 0.5 μm thick and with y greater than x and z less than about 0.3.

5. Cemented carbide insert of claim 4 wherein in said first innermost layer, y is greater than about 0.8 and z=0, and in said second layer, x is greater than about 0.5 and the second layer thickness is less than about 6 μm.

6. Method of making coated cemented carbide inserts with excellent toughness properties comprising providing a cemented carbide substrate WC having an average grain size of from about 0.5 to about 1.5 μm, from about 8 to about 11 wt-% Co, and from about 0.2 to about 0.5 wt-% Cr by wetmilling powders with pressing agent, and small additions of carbon black or pure tungsten powder to obtain a CW-ratio in the sintered inserts of from about 0.80 to about 0.90 in a slurry, drying the slurry to a powder, compacting and sintering and after conventional post sintering treatment depositing a coating comprising:
a first, innermost layer of TiCₓN_{y}O_{z} with x+y+z=1, with equiaxed grains with size less than about 0.5 μm and a total thickness less than about 1.5 μm, using known CVD-methods,
a layer of TiCₓN_{y}O_{z} with x+y+z=1 with a thickness of from about 1 to about 8 μm, with columnar grains and with an average diameter of about less than about 5 μm by MTCVD-technique with acetonitrile as the carbon and nitrogen source for forming the layer in the temperature range of from about 700 to about 900° C.,
a layer of smooth fine-grained grain size from about 0.5 to about 2 μm Al₂O₃ consisting essentially of the κ-phase with a thickness of from about 0.5 to about 5 μm, using known CVD-methods,
a further layer less than about 1 μm thick, of TiCₓN_{y}O_{z} with x+y+z=1 using known CVD-methods,
fully or partly removing the outermost TiCₓN_{y}O_{z}-layer and Al₂O₃-layer on at least 80% of the rake face surface area between the edge line and 100 μm inwards in the direction perpendicular to the edge line.

7. A method according to claim 6 wherein said substrate comprises from about 9.5 to about 10.5 wt-% Co.

8. A method according to claim 6 wherein in said first layer, y greater than z and z is less than about 0.2 and said first layer has a total thickness greater that about 0.1 μm, in said second layer, z=0, x and y are each greater than about 0.3 and said second layer has a thickness of from about 2 to about 7 μm and said columnar grains have an average diameter of from about 0.1 to about 2 μm, said Al₂O₃ has a thickness of from about 0.5 to about 2 μm and said further layer of TiCₓN_{y}O_{z} being from about 0.1 to about 0.5 μm thick and with y greater than x and z less than about 0.3.

9. A method of claim 6 wherein in said first innermost layer, y is greater than about 0.8 and z=0, and in said second layer, x is greater than about 0.5 and the second layer thickness is less than about 6 μm.

10. A method of claim 6 wherein the removal of said layers is done by wet-blasting the coated surface with fine-grained Al₂O₃ powder.
